(19) United States
(12) Patent Application Publication
(10) Pub. No.: US 2020/0361336 A1
(43) Pub. Date: Nov. 19, 2020

(54) MANAGEMENT APPARATUS, APPARATUS, AND COMPUTER-READABLE STORAGE MEDIUM

(71) Applicant: HONDA MOTOR CO., LTD., Tokyo (JP)

(72) Inventors: Shinichi YOKOYAMA, Wako-shi (JP); Tomohide HARAGUCHI, Wako-shi (JP); Naoya YASUDA, Tokyo (JP); Hiromasa SHIGETA, Tokyo (JP); Keiichi IGUCHI, Tokyo (JP)

(21) Appl. No.: 16/944,623

(22) Filed: Jul. 31, 2020

Related U.S. Application Data
(63) Continuation of application No. PCT/JP2018/045204, filed on Dec. 10, 2018.

(30) Foreign Application Priority Data
Feb. 6, 2018 (JP) 2018-019570
Mar. 9, 2018 (JP) 2018-043460

(51) Int. Cl. B60L 58/10; B60L 58/30; G01R 31/382; G01R 31/385; G01R 21/133

(52) U.S. Cl. CPC B60L 58/10; B60L 58/30; G01R 21/133; G01R 31/385; G01R 31/382

(57) ABSTRACT

A management apparatus that manages an electric power device of an electric power consumer, comprises: an obtaining unit configured to obtain characteristic information of the electric power device as information related to an environmental load; and a planning unit configured to plan a priority rank of an operation of the electric power device in utilization of electric power of the electric power device based on the characteristic information obtained by the obtaining unit.

### CROSS-REFERENCE TO RELATED APPLICATION(S)

This application is a continuation of International Patent Application No. PCT/JP2018/045204 filed on Dec. 10, 2018, which claims priority to and the benefit of Japanese Patent Application No. 2018-019570 filed on Feb. 6, 2018, and Japanese Patent Application No. 2018-043460 filed on Mar. 9, 2018 the entire disclosures of which are incorporated herein by reference.

### BACKGROUND OF THE INVENTION

### Field of the Invention

The present invention relates to a management apparatus that manages an electric power device of an electric power consuming party, an apparatus, a computer-readable storage medium.

### Description of the Related Art

In recent years, a resource aggregator is known that organizes the electric power sources (resources) of a plurality of consuming parties who are spread in a region so as to satisfy a request concerning the amount of electric power demand in the electric power market. A mechanism in which the resource aggregator controls the amount of electric power demand is known as a demand response, and a consuming party can earn compensation from the aggregator by participating in such a mechanism (Non-Patent Literature 1).

Patent Literature 1 describes generation of a resource group based on resource profiles, and control on resources in accordance with this resource group and control scenarios. The resource profiles describe information related to resource properties and information related to a contract of a demand response program.

### CITATION LIST

### Patent Literature

Patent Literature 1: Japanese Patent No. 5944574

### Non-Patent Literature

Non-Patent Literature 1: “About the Energy Resource Aggregation Business” on the Internet (URL:http://www.meti.go.jp/committee/kenkyukai/energy_enviromnent/energy_resource/pdf/001_04_00.pdf)

### SUMMARY OF THE INVENTION

### Technical Problem

Patent Literature 1 describes a lead time, an assumed amount of control, a lamp period (a period until a target value of electric power consumption is reached), and the like as information related to resource properties. Furthermore, according to Patent Literature 1, when a resource group is generated, the resources are ranked based on information of licensing fees and lamp periods.

The status of use of a resource changes from moment to moment in accordance with, for example, a daily life of a consuming party. Meanwhile, in utilization of an electric power device, it is desirable that control on the operation of the electric power device exert a small influence on a consuming party.

An object of the present invention is to provide a management apparatus, an apparatus, and a computer-readable storage medium that optimally plan the operation of an electric power device of an electric power consumer in utilization of the electric power device.

### Solution to Problem

A management apparatus according to the present invention is a management apparatus that manages an electric power device of an electric power consumer, comprising: an obtaining unit configured to obtain characteristic information of the electric power device, the characteristic information including at least information related to an environmental load; and a planning unit configured to plan a priority rank of an operation of the electric power device in utilization of electric power of the electric power device based on the characteristic information obtained by the obtaining unit.

A computer-readable storage medium that stores a program that, in order to manage an electric power device of an electric power consumer, causes a computer to execute: an obtaining step of obtaining characteristic information of the electric power device as information related to an environmental load; and a planning step of planning a priority rank of an operation of the electric power device in utilization of electric power of the electric power device based on the characteristic information obtained in the obtaining step.

### Advantageous Effects of Invention

According to the present invention, the operation of an electric power device of an electric power consumer can be optimally planned in utilization of the electric power device. Other features and advantages of the present invention will become apparent from the following description with reference to the attached drawings. Note that the same reference numerals denote the same or like constituents in the attached drawings.

Further features of the present invention will become apparent from the following description of exemplary embodiments with reference to the attached drawings.

### BRIEF DESCRIPTION OF THE DRAWINGS

The attached drawings are included in and constitute a part of the specification, illustrate an embodiment of the present invention, and are used, together with a description thereof, to explain the principle of the present invention.

FIG. 1 is a diagram showing an overall configuration of a VPP system.

FIG. 2A is a diagram showing configurations of respective apparatuses of the VPP system.

FIG. 2B is a diagram showing configurations of respective apparatuses of the VPP system.

FIG. 2C is a diagram showing configurations of respective apparatuses of the VPP system.

FIG. 3A is a diagram showing a sequence of processing performed between a consuming party and an aggregator.

FIG. 3B is a diagram showing a sequence of processing performed between the consuming party and the aggregator.

FIG. 4 is a flowchart showing processing of database registration.

FIG. 5 is a flowchart showing processing of demand prediction.

FIG. 6 is a flowchart showing processing of resource utilization planning.

FIG. 7 is a flowchart showing processing of resource utilization planning.

FIG. 8 is a flowchart showing processing of resource utilization planning.

FIG. 9 is a flowchart showing processing for controlling the operations of resources.

FIG. 10 is a flowchart showing processing for setting the prices of compensation.

FIG. 11A is a diagram showing a sequence of processing performed between the consuming party and the aggregator.

FIG. 11B is a diagram showing a sequence of processing performed between the consuming party and the aggregator.

FIG. 12 is a flowchart showing processing for setting the price of compensation.

FIG. 13 is a diagram showing association between resources and environmental load indexes.

### DESCRIPTION OF THE EMBODIMENTS

The following describes an embodiment of the present invention with reference to the drawings. The present invention is not limited to the following embodiment, and also encompasses changes and modifications of constituents within the scope of the intent of the present invention. Furthermore, all of the combinations of the features described in the present embodiment are not necessarily indispensable for the present invention. Note that the same constituent elements are given the same reference numeral, and a description thereof will be omitted.

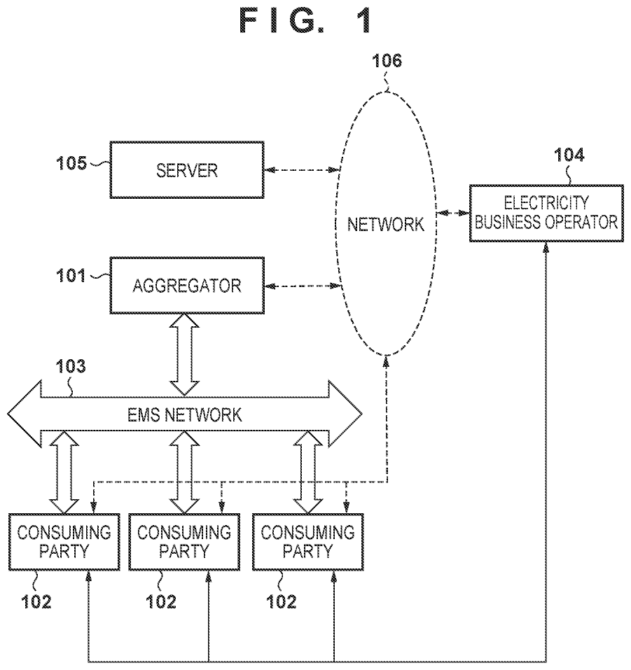

FIG. 1 is a diagram showing an overall configuration of a VPP (Virtual Power Plant) system according to the present embodiment. As shown in FIG. 1, the VPP system according to the present embodiment includes an aggregator 101, consuming parties 102, an electricity business operator 104, and a server 105. The electricity business operator 104 is, for example, a retail electricity business operator or an electricity transmission/distribution business operator that supplies electric power to the consuming parties 102, which are households, factories, and the like. In the present embodiment, the consuming parties 102 refer directly to such facilities as households and factories, but are particularly referred to as electric power consumers, or simply consumers, especially when they refer to people who receive a VPP service as opposed to the consuming parties 102.

The aggregator 101 is positioned between the consuming parties 102 and the electricity business operator 104, and provides the VPP service to the consuming parties 102. In the VPP service, for example, electricity generation systems and electricity storage systems of the consuming parties 102 are utilized in order to meet a request from the electricity business operator 104. The aggregator 101 establishes the VPP through integration and control of energy management systems of the consuming parties 102 in a predetermined region via an EMS network 103. The EMS network 103 may be dedicated lines, or may include telephone lines. When the consuming parties 102 are household facilities (referred to as household consuming parties 102), the energy management systems of the consuming parties 102 are systems that manage electric energies that are used in the households (HEMS: Home Energy Management System). On the other hand, when the consuming parties 102 are commercial facilities (referred to as industrial consuming parties 102), the energy management systems are systems that manage electric energies that are used in the facilities (BEMS: Building Energy Management System). The aggregator 101 can integrate and control the energy management systems of the consuming parties 102 by making use of, for example, IoT (Internet of Things) data of the consuming parties 102.

The server 105 manages information of the consuming parties 102 and information of the resources of the energy management systems of the consuming parties 102. The resources will he described later. Furthermore, the aggregator 101, the consuming parties 102, the electricity business operator 104, and the server 105 are configured in such a manner that they can mutually communicate via a network 106 and can mutually exchange mails and data.

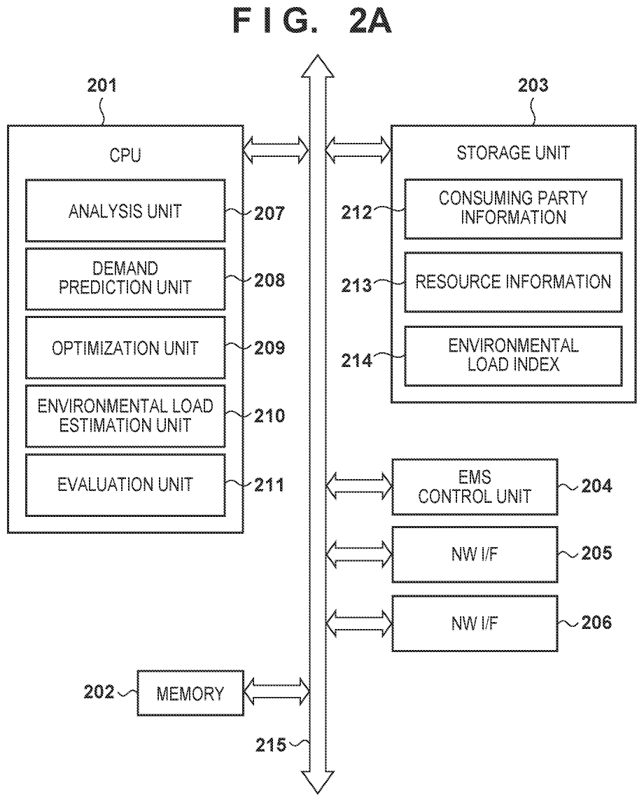

FIG. 2A is a diagram showing a configuration of the aggregator 101. The configurations of FIGS. 2A to 2C can be a computer capable of executing the present invention pertaining to a program. Respective blocks shown in FIG. 2A are connected in such a manner that they can mutually communicate via a system bus 215. A CPU 201 controls the aggregator 101 integrally by, for example, reading out a program stored in a storage unit 203 into a memory 202 and executing the program. Furthermore, as will be described later, the CPU 201 includes blocks for realizing the behaviors in the present embodiment. The storage unit 203 stores parameters, data, and the like that are necessary for an EMS control unit 204 to control the operations of respective resources of the consuming parties 102, in addition to the basic program, data, and the like for the behaviors of the aggregator 101. The storage unit 203 also stores, for example, consuming party information 212 and resource information 213 as information that are used in the present embodiment. The storage unit 203 further stores a market trade program that provides a function of performing selling and buying in the electric power market.

The consuming party information 212 is information related to consumers, and is, for example, the contents of contracts that the consumers make with an administrator of the aggregator 101 in using the VPP service. The VPP service is a service in which utilization of the resources by the aggregator 101 enables the consumers to earn compensation, and known examples of which include negawatt trading and posiwatt trading. The consumers can participate in such trading by signing contracts with the aggregator 101. Then, after the contracts have been made, the consumers receive a command for controlling the electric power demand from the aggregator 101, and the resources of the energy management systems are remotely controlled by the aggregator 101 via the EMS network 103. The consumers earn compensation in exchange for utilization by the aggregator 101 of the resources of the energy management systems of the consuming parties 102. Here, control on the electric power demand may, for example, aim to restrain or promote the demand relative to the amount of electric power supply from the electricity business operator 104, and aim to stabilize the frequency in an electric power system.

The contents of the contracts that the consumers sign with the administrator of the aggregator 101 include, for example, the type of the VPP service, the name of the region, the contracted electric power, and the payee/payment method of the compensation. Furthermore, the contents of the contracts also include information specific to the consumers, for example, such information as address information, housing information, a family structure, and contact information. Furthermore, the contents of the contracts include, for example, an increase or decrease in the amount of electric power demand that can be dealt with by the consuming parties 102. Furthermore, the contents of the contracts also include information indicating, for example, what kind of electric power devices are owned by the consumers. In the case of household consuming parties 102, the owned electric power devices are, for example, an air conditioning device, a lighting device, a home appliance, an electricity generation system such as solar panels, an electricity storage system such as an onboard battery of an electric vehicle (EV), and so forth.

The resource information 213 is information related to the resources of the energy management systems of the consuming parties 102. Here, the resources refer to the aforementioned devices and systems. The resource information 213 includes, for example, such device information as a model, a model number, an activation period, a stabilization period, the amount of electricity generation, standby power, energy efficiency, maintenance information, a malfunction history, a behavior history, the year/month/date of purchase, and the duration of time in which the operation is possible. Furthermore, the resource information 213 also includes information related to environmental loads of respective resources, and includes, for example, the amount of CO₂ (carbon dioxide) emission, sound of noise, the amount of vibration, and emission (electric noise). Furthermore, the resource information 213 may include output information corresponding to the types of the resources, and may include temperature information in relation to, for example, an electric water heater and a floor heating device. Furthermore, it may include information related to a traveled distance in relation to an electric vehicle. The information related to the traveled distance includes, for example, a cumulative traveled distance and intended travel information, such as the date/time and the extent of the next intended travel. The date/time of the next intended travel may be, for example, estimated from the result of monitoring of the resource information 213, which will be described later, or obtained from utilization plans submitted from the consuming parties and user interfaces. Furthermore, the resource information 213 may include other information obtained from these pieces of information. For example, it may include life information of the resources that is obtained from the maintenance information and the year/month/date of purchase. Furthermore, the resource information 213 may also include IoT data (e.g., sensor information) obtained from the HEMSs in which the energy management systems are configured.

The consuming party information 212 is obtained when, for example, the consumers make contracts with the administrator of the aggregator 101. On the other hand, the resource information 213 need not be provided by the consumers, and is obtained by the aggregator 101 from the energy management systems of the consuming parties 102. In the present embodiment, the EMS control unit 204 of the aggregator 101 obtains the resource information 213 from the energy management systems of the consuming parties 102 via the EMS network 103; thus, in the case of this configuration, the consumers need not provide the administrator of the aggregator 101 with, for example, a period in which the owned electric vehicle can be utilized as a utilization plan. Furthermore, the storage unit 203 stores environmental load indexes 214. The environmental load indexes 214 will be described later.

In FIG. 2A, the consuming party information 212 and the resource information 213 are registered with a database configured in the storage unit 203 of the aggregator 101; however, they may be registered with a database configured in a storage unit 234 of the server 105, which will be described later, and may be obtained by the CPU 201 through access to the server 105 as necessary.

The EMS control unit 204 controls respective resources of the energy management systems of the consuming parties 102 via the EMS network 103. For example, in response to a request from the electricity business operator 104 to restrain the electric power demand, the EMS control unit 204 discharges storage batteries connected to solar electric generators. A network interface (NW I/F) 205 is an interface for enabling communication with the EMS network 103. Also, a network interface (NW I/F) 206 is an interface for enabling communication with the network 106, and is composed of including, for example, an NIC (Network Interface Card).

As shower FIG. 2A, the CPU 201 includes an analysis unit 207, a demand prediction unit 208, an optimization unit 209, an environmental load estimation unit 210, and an evaluation unit 211. The analysis unit 207 analyzes the statuses of electric power use of respective resources of the consuming parties 102. In the present embodiment, the EMS control unit 204 of the aggregator 101 monitors such information as the statuses of electric power use of respective resources of the energy management systems of the consuming parties 102 via the EMS network 103, and can perform real-time collection of, for example, a change in the battery capacity of the onboard battery of the electric vehicle and the like. The analysis unit 207 analyzes time sections in which respective resources are used and the like based on, for example, the result of monitoring by the EMS control unit 204.

Based on the result of analysis by the analysis unit 207, the demand prediction unit 208 predicts a fluctuation in the electric power demand throughout the region managed by the aggregator 101. Based on the result of analysis by the analysis unit 207, the optimization unit 209 optimizes the operations of respective resources of the energy management systems of the consuming parties 102 (a utilization planning) so as to satisfy a request from the electricity business operator 104 concerning the electric power demand. The environmental load estimation unit 210 estimates environmental loads associated with the operations of respective resources of the energy management systems of the consuming parties 102. The evaluation unit 211 performs evaluation for setting the compensation to be paid to the consumers. For example, the evaluation unit 211 sets the compensation to be paid to the consumers based on the environmental loads estimated by the environmental load estimation unit 210.

FIG. 2B is a diagram showing a configuration of a consuming party 102. Respective blocks shown in FIG. 2B are connected in such a manner that they can mutually communicate via a system bus 230. The configuration shown in FIG. 2B may be provided as, for example, a control system of the HEMS of a household consuming party 102. A CPU 221 controls the consuming party 102 integrally by, for example, reading out a program stored in a storage unit 225 into a memory 222 and executing the program. The storage unit 225 stores the basic program and data for the behaviors of the consuming party 102, and parameters, data, and the like that are necessary for an EMS control unit 226 to control the operations of respective resources.

A network interface (NW I/F) 223 is an interface for enabling communication with the EMS network 103. Also, a network interface (NW I/F) 224 is an interface for enabling communication with the network 106, and is composed of including, for example, an NIC.

The EMS control unit 226 controls the operations of respective resources of the energy management system of the consuming party 102. In the present embodiment, the EMS control unit 226 activates respective resources, or stops the operations of respective resources, by receiving a control instruction from the EMS control unit 204 of the aggregator 101. An electric device 227, an electricity storage system 228, and an electricity generation system 229 are resources whose operations are controlled by the EMS control unit 226. The electric device 227 is, for example, lighting equipment or a home appliance. The electricity storage system 228 is, for example, an onboard battery of an electric vehicle or a fuel cell vehicle, or a storage battery. Furthermore, the electricity generation system 229 is, for example, a solar electric generator. The EMS control unit 226 can improve the self-sufficiency rate within the consuming party 102 through, for example, control to discharge the electricity storage system 228 and the electricity generation system 229.

FIG. 2C is a diagram showing a configuration of the server 105. Respective blocks shown in FIG. 2C are connected in such a manner that they can mutually communicate via a system bus 235. A CPU 231 controls the server 105 integrally by, for example, reading out a program stored in a storage unit 234 into a memory 232 and executing the program. The storage unit 225 stores, for example, the basic program and data for the behaviors of the server 105. Furthermore, the storage unit 225 may be established as a database for managing data that is used in the VPP service and can be big data. For example, as mentioned earlier, the storage unit 225 may store the consuming party information 212 and the resource information 213. A network interface (NW I/F) 233 is an interface for enabling communication with the network 106, and is composed of including, for example, an NIC.

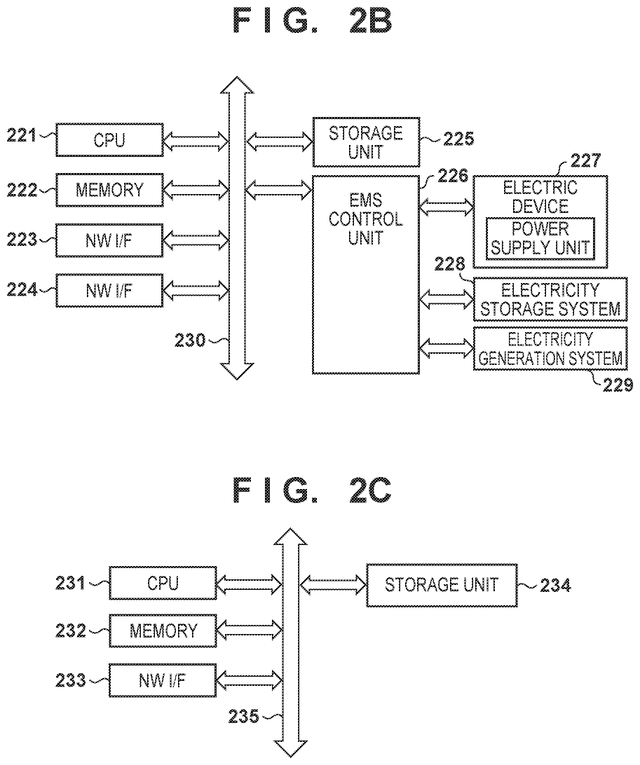

FIG. 3A is a sequence diagram showing processing that is performed among the aggregator 101, the consuming party 102, and the electricity business operator 104 in the VPP system of FIG. 1. First, in step 301, a contract for using the VPP service is signed between the consuming party 102 and the aggregator 101. Thereafter, the aggregator 101 receives a request from the electricity business operator 104 to control the electric power demand in step 302, and then plans utilization of the resources of the energy management system of the consuming party 102 based on the result of analysis by the analysis unit 207 in step 303. Here, the request from the electricity business operator 104 to control the electric power demand is, for example, a request to restrain or promote the electric power demand. Then, in step 304, the aggregator 101 utilizes the resources of the energy management system of the consuming party 102 in conformity with the utilization plan. In step 305, the aggregator 101 transmits a record of control on the electric power demand (the amount of demand control) to the electricity business operator 104. Thereafter, in step 306, the electricity business operator 104 pays compensation corresponding to the record to the aggregator 101. Then, in step 307, the aggregator 101 pays compensation (incentive) to the consuming party 102.

In FIG. 3A, the utilization of resources is started after receiving the request from the electricity business operator 104 to control the electric power demand; meanwhile, in FIG. 3B, the utilization of resources is started after the aggregator 101 has predicted the electric power demand. First, in step 311, a contract for using the VPP service is signed between the consuming party 102 and the aggregator 101. Thereafter, in step 312, based on the result of analysis by the analysis unit 207, the aggregator 101 predicts a fluctuation in the electric power demand throughout the region managed by the aggregator 101. Then, in step 313, the aggregator 101 plans the utilization of the resources of the energy management system of the consuming party 102 based on the result of analysis by the analysis unit 207 so as to reduce the predicted fluctuation in the electric power demand. Then, in step 314, the aggregator 101 utilizes the resources of the energy management system of the consuming party 102 in conformity with the utilization plan. Note that the aggregator 101 thereafter pays compensation to the consuming party 102, although not shown in FIG. 3B.

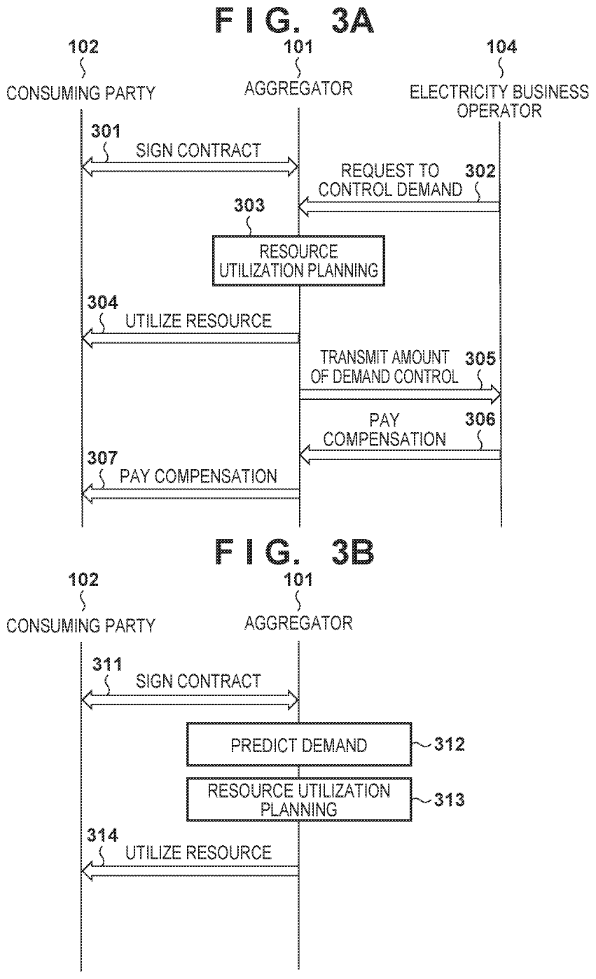

FIG. 4 is a flowchart showing processing for registering the consuming party information 212 and the resource information 213 with a database. The processing of FIG, 4 is executed by the CPU 201 of the aggregator 101. In S101, the CPU 201 obtains, for example, the content of a contract signed between the administrator of the aggregator 101 and a consumer via an input device (not shown), such as a keyboard. Then, the CPU 201 registers the obtained consuming party information 212 with the database configured in the storage unit 203. Alternatively, the CPU 201 may register the obtained consuming party information 212 with the database configured in the storage unit 203 of the server 105 via the network 106.

In S102, the CPU 201 causes the EMS control unit 204 to start monitoring the resources of the energy management system of the consuming party 102 with whom the contract has been signed. The EMS control unit 204 monitors such information as the statuses of electric power use of respective resources via the EMS control unit 226 of the consuming party 102. Information included in the resource information 213 can be the target of monitoring. In S103, the EMS control unit 204 obtains, for example, the amount of electric power use (Wh) at a predetermined time interval based on the result of monitoring in S102; the obtained information is registered as the resource information 213 with the database configured in the storage unit 203 in S104. Alternatively, the CPU 201 may register the obtained resource information 213 with the database configured in the storage unit 203 of the server 105 via the network 106. Thereafter, the processing of FIG. 4 is ended.

In the foregoing description, the EMS control unit 204 of the aggregator 101 performs monitoring (surveillance) of the resources of the energy management system of the consuming party 102 in S102; however, the EMS control unit 226 of the consuming party 102 may periodically transmit log information of the amount of electric power use to the EMS control unit 204 of the aggregator 101.

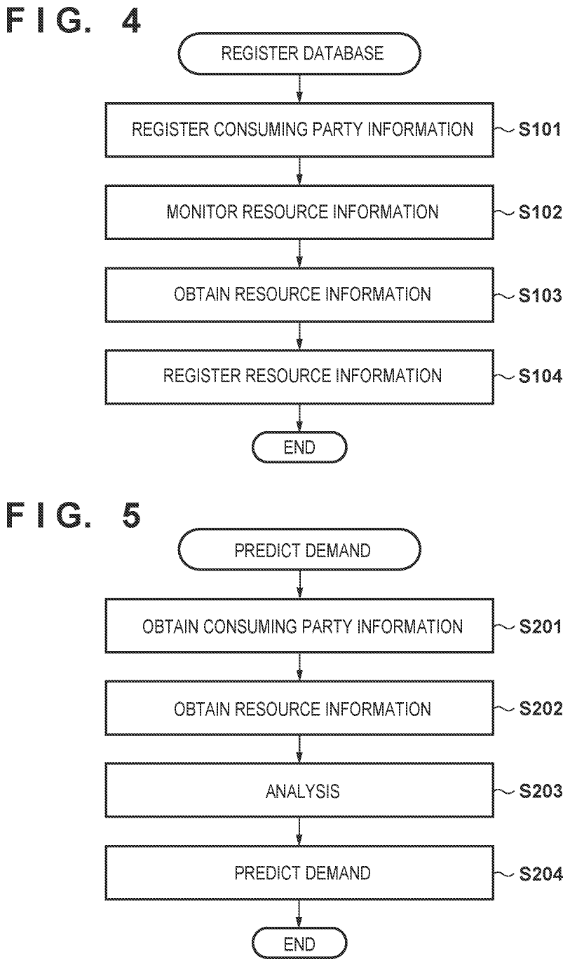

FIG. 5 is a flowchart showing processing of demand prediction in step 312 of FIG. 3B. The processing of FIG. 5 is executed by the demand prediction unit 208 of the CPU 201. In S201, the CPU 201 obtains the consuming party information 212 that has been registered with the database through the processing of FIG. 4. In S202, the CPU 201 obtains the resource information 213 that has been registered with the database through the processing of FIG. 4.

In S203, the CPU 201 analyzes the resource information 213 obtained in S202. In S203, for example, changes in the amounts of electric power use and time sections of use, per day, of respective resources of the energy management systems of the consuming parties 102 are obtained as a result of analysis. For example, based on the statuses of connection of electric vehicles to connection ports (not shown), the time sections in which the electric vehicles are used (in other words, the time sections in which they are not used) are obtained as a result of analysis. The tendencies of the amounts of electric power use of respective resources in a predetermined period, such as several hours, several days, and several weeks, may be obtained as a result of analysis.

In S704, the CPU 201 predicts the electric power demand of the future based on the result of analysis obtained in S203. For example, the CPU 201 predicts the electric power demand at a time point that will take place several days later, several weeks later, one month later, and so forth. For example, assume that the analysis of S203 is performed in mid-July, and with respect to a certain consuming party 102, the tendency of 10% increase in the amount of electric power use during predetermined two weeks has been obtained as a result of such analysis. The CPU 201 predicts the electric power demand two weeks ahead from the result of analysis on respective consuming parties 102 in the region managed by the aggregator 101, for example, increasing curves of respective consuming parties 102. Then, an increase in the electric power demand in early August throughout this region is predicted. Furthermore, at the time of prediction, information that is not dependent on the consuming parties 102, such as daylight information and ambient temperature information, may also be used.

The electric power demand may be predicted based on the reliability degrees of the consuming parties 102. For example, when a consumer is operating the resources in line with a utilization plan presented to the aggregator 101, the reliability degree of the consuming party 102 is increased. On the other hand, when a consumer frequently changes a utilization plan presented to the aggregator 101, the reliability degree of the consuming party 102 is lowered. Then, the electric power demand may be predicted by preferentially using the result of analysis on consuming parties 102 who have a certain reliability degree or higher within the region.

After S204, the processing of FIG. 5 is ended. The result of prediction of the electric power demand in S204 is used, for example, as follows. When the demand prediction unit 208 of the CPU 201 has predicted that the amount of electric power demand in the region will have a 15% increase two weeks ahead, the operations of the resources of the energy management systems of respective consuming parties 102 are controlled so as to reduce a fluctuation corresponding to such an increase. For example, the self-sufficiency rates based on the electricity generation systems 229 and the electricity storage systems 228 may be increased in accordance with the rate of predicted increase in the amounts of electric power use of respective consuming parties 102.

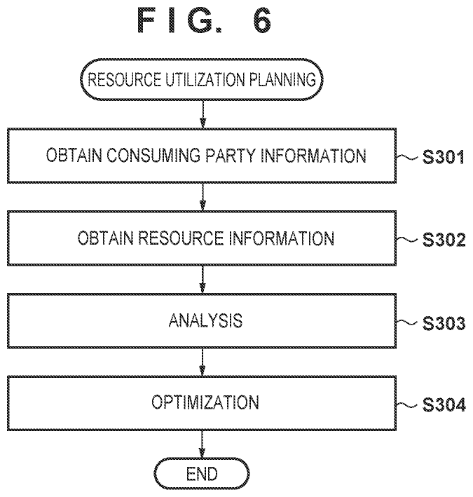

FIG. 6 is a flowchart showing processing of resource utilization planning. The processing of FIG. 6 is started, for example, when the aggregator 101 has received a request from the electricity business operator 104 to control the electric power demand. The following describes an exemplary case where, upon receiving a request to restrain the electric power demand, the operations of resources are optimized so as to improve the self-sufficiency rates of the consuming parties 102. Also, the processing of FIG. 6 is executed by the analysis unit 207 and the optimization unit 209 of the CPU 201 of the aggregator 101. In S301, the CPU 201 obtains the consuming party information 212 that has been registered with the database through the processing of FIG. 4. In S302, the CPU 201 obtains the resource information 213 that has been registered with the database through the processing of FIG. 4.

In the present embodiment, IoT information of the HEMSs is obtained, in addition to the amounts of electric power use of the resources, through monitoring. For example, signals from sensors are also obtained. Sensor signals are, for example, signals indicating human sensing (the existence of heat sources), a temperature, a humidity, brightness, air components, a volume, and the like.

In S303, the CPU 201 analyzes the statuses of electric power use (the statuses of use of the resources) from the resource information 213 obtained in S302. In S303, changes in the amounts of electric power use and time sections of use, per day, of respective resources of the energy management systems of the consuming parties 102 are recognized. For example, based on the statuses of connection of electric vehicles to connection ports (not shown), the time sections in which the electric vehicles are used (in other words, the time sections in which they are not used) are recognized.

Note that the statuses of electric power use of respective sources in a predetermined period, such as several hours, several days, and several weeks, rather than on a daily basis, may be recognized. At this time, when the statuses of electric power use of the resources show a notable fluctuation, this fluctuation may be excluded from the target of analysis based on predetermined conditions. For example, erroneous handling of an electric device by a consumer and the status of absence of a family due to, for example, a short-term (e.g., one-night) trip based on sensor information may be recognized, and the relevant result of monitoring of the amount of electric power use may be excluded from the analysis.

That is to say, in the present embodiment, as the analysis is performed in S303 with exclusion of the result of monitoring related to erroneous handling and the like by a consumer and an unusual activity of a consumer, it is possible to obtain information of the statuses of electric power use that are in better conformity with ordinary activity patterns of consumers. As a result, when, for example, the operations of resources are controlled for the purpose of restraining the electric power demand, it is possible to prevent such restraint from being exercised beyond necessity.

In S304, with use of the result of analysis in S303, the CPU 201 optimizes the operations of respective resources of the energy management systems of the consuming parties 102 (utilization planning) so as to satisfy a request from the electricity business operator 104 to control the electric power demand.

For example, when the electricity business operator 104 has made a request to restrain the amount of electric power demand, the CPU 201 decides on the amounts of restraint in the demand of respective consuming parties 102 based on the amount of restraint in the demand requested from the electricity business operator 104. The CPU 201 decides on the operation schedules of respective resources of the energy management systems of the consuming parties 102 so as to create negawatts and posiwatts based on the decided amounts of restraint in the demand.

For example, when the amount of electric power use per day is 12 kWh and a 10% reduction is the goal, the CPU 201 plans the operation schedules of the resources based on, for example, the amount of surplus electric power, the electricity storage capacities of the electricity storage systems, and whether the energy created by the solar electric generators is to be used for self-sufficiency or is to be sold. Assume that, at this time, a plurality of resource candidates that can be operated to achieve the goal have been specified based on, for example, profile information (performance information) of the resources. According to the present embodiment, in this case, resources to be preferentially operated are decided on based on characteristic information that is obtained as a result of monitoring.

For example, the CPU 201 may decide on resources to be preferentially operated based on the statuses of use of the resources that are obtained as characteristic information as a result of monitoring. For example, when it has been determined that a consumer does not use an electric vehicle during daytime as a result of analysis in S303, an onboard battery of the electric vehicle is preferentially operated as a resource in order to increase the self-sufficiency rate. Then, the onboard battery of the electric vehicle is discharged together with a solar electric generator system, thereby increasing the self-sufficiency rate. Also, the statuses of use of the resources may be the statuses of future use that can be estimated. For example, when a consuming party 102 has a plurality of onboard batteries, the usable battery capacities of respective onboard batteries at present are decided on based on the date/time and the extent of the next intended travel of an electric vehicle. Then, priority ranks of the plurality of onboard batteries may be decided on based on the decided usable battery capacities.

Furthermore, the CPU 201 may decide on resources to be preferentially operated based on resource properties and the state of a consumer that are obtained as characteristic information as a result of monitoring. For example, there is a case where it is desirable not to operate an onboard battery of an electric vehicle while the consumer is at home because the onboard battery generates noise, vibration, and emissions while being operated. In view of this, when it has been determined that the consumer is absent from, for example, sensor information of a smart home, the CPU 201 preferentially operates (discharges) the onboard battery of the electric vehicle as a resource for increasing the self-sufficiency rate. On the other hand, when it has been determined that the consumer is at home, the priority degree of the operation of a resource that generates noise and vibration of a predetermined level or more, such as the onboard battery of the electric vehicle, is lowered, and instead, a storage battery is preferentially operated. Furthermore, even when it has been determined that the consumer is at home, resources to be preferentially operated may be decided on based on the state of the consumer. For example, upon entering into an automatic lights-out mode (the consumer has gone to sleep) as a function of the smart home, the priority degree of the operation of a resource that generates noise and vibration of a predetermined level or more may be lowered. In addition, priority ranks of a plurality of resources may be decided on based on the levels of noise and vibration.

Furthermore, in a case where the activation period and the stabilization period are obtained as resource properties, when it has been determined that a consumer is at home, priority ranks of a plurality of resources may be decided on in ascending order of the activation period and the stabilization period. Moreover, in a case where the standby power is obtained as a resource property, when it has been determined that a consumer is absent, priority ranks of a plurality of resources may be decided on in ascending order of the standby power.

Also, the CPU 201 may decide on resources to be preferentially operated based on maintenance information of resources that is obtained as characteristic information as a result of monitoring. For example, temperature information of the installation environment of a storage battery and voltage information at the time of charging are obtained in advance as the resource information 213. Then, the CPU 201 may obtain life information of the storage battery from these pieces of information. For example, when the remaining life of a storage battery of a consuming party 102 is lower than a threshold, the CPU 201 lowers the priority degree of the operation of the storage battery. This makes it possible to prepare for use in a time of emergency, such as on the occurrence of an earthquake. On the other hand, when the amount of restraint in the demand requested from the electricity business operator 104 is large on the occurrence of an earthquake and the like, the priority degree of the operation of this storage battery is increased so as to increase the self-sufficiency rate, even if the remaining life is lower than the threshold. Furthermore, priority ranks of a plurality of storage batteries may be decided on based on life information. Moreover, in a case where the electricity business operator 104 has issued a request to promote the demand, when the operation schedules of respective resources are decided on based on maintenance information, resources to be preferentially operated may be decided on in order starting with, for example, resources that periodically undergo maintenance and resources with long remaining lives.

Also, the criteria for deciding on priority ranks of the operations of respective resources may be changed in accordance with the resource information 213. For example, in S102, density information from a CO₂ sensor that is installed in the BEMS of an industrial consuming party 102 is monitored. Then, when the CO₂ density is equal to or lower than a threshold, priority ranks of the plurality of resources are decided on based on maintenance information and the like, and when the CO₂ density is higher than the threshold, priority ranks of the plurality of resources are decided on based on the amounts of CO₂ emission of respective resources.

Also, the criteria for deciding on a priority rank may be changed in accordance with other configurations. For example, the storage unit 203 of the aggregator 101 may hold a matrix table in which each state of a consumer is associated with the criteria to be used. In the matrix table, the criteria for deciding on a priority rank (e.g., the status of use of a resource, resource properties, and maintenance information) are set with respect to, for example, each of whether the consumer is in an at-home state or an absent state, whether the consumer is in a sleeping state, and so forth. Furthermore, it is possible to adopt a configuration in which weights are applied to respective priority ranks based on the above-described matrix table, and the weights are sequentially updated in accordance with the result of monitoring. For example, upon recognizing a state where there is almost no difference in the remaining life among the resources as a result of monitoring the execution of maintenance on respective resources, the weight for the maintenance information is reduced. When there are a plurality of criteria that can be applied with respect to a predetermined state of the consumer, a criterion with the largest weight may be used. In addition, a criterion with a weight equal to or smaller than a threshold may be deleted from the matrix table, and a criterion with a weight larger than the threshold may be added to the matrix table.

As described above, according to the present embodiment, a more optimal resource utilization plan can be made. Note that the behaviors of respective examples described above may be combined with one another.

FIG. 6 has been described under the assumption that it is started when the aggregator 101 has received a request from the electricity business operator 104 to control the electric power demand. However, the processing of FIG. 6 may be started when the electric power demand has been predicted in FIG. 5 and fluctuations in the amount of the predicted electric power demand are leveled.

Also, according to the above-described embodiment, the CPU 201 of the aggregator 101 obtains characteristic information by analyzing the resource information 213, which is obtained as a result of monitoring. However, the CPU 221 of a consuming party 102 may obtain characteristic information by analyzing the result of monitoring of respective resources. In this case, the CPU 221 of the consuming party 102 transmits the obtained characteristic information to the aggregator 101. The aggregator 101 manages the characteristic information received from the consuming party 102 in the storage unit 203. Furthermore, the CPU 221 of the consuming party 102 may transmit the characteristic information to the aggregator 101 and the characteristic information managed in the storage unit 203 may be updated only when the characteristic information has changed. This configuration can reduce the communication load on the EMS network 103.

In FIG. 6, the consumers need not present the resource utilization plans. On the other hand, however, there is a case where the consumers present the resource utilization plans and the aggregator 101 utilizes the resources of the energy management systems of the consuming parties 102 in conformity with such utilization plans. This case will be described below.

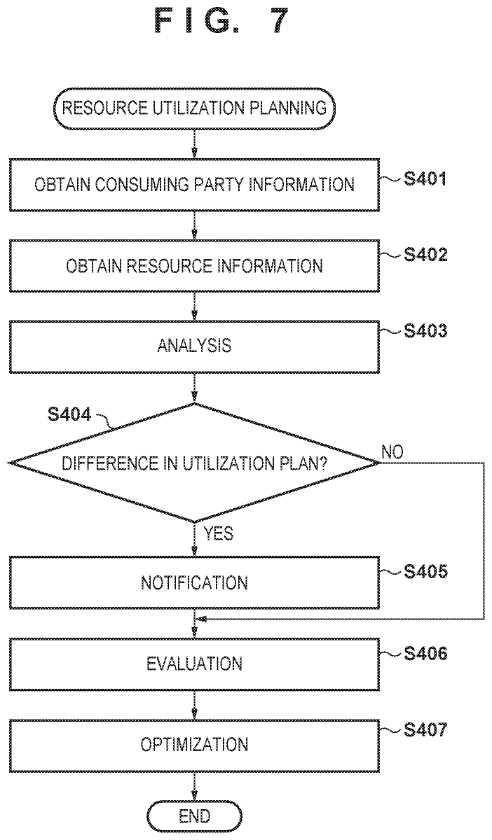

FIG. 7 is a flowchart showing processing of resource utilization planning for the case where the consumers have presented the resource utilization plans. The resource utilization plans presented from the consumers refer to, for example, utilization plan documents on which the consumers described operation time sections/non-operation time sections of respective resources when the consumers signed contracts for the VPP service with the administrator of the aggregator 101 (step 301 of FIGS. 3A and 3B). The CPU 201 of the aggregator 101 accepts the contents of the presented utilization plan documents via an input device (not shown), such as a keyboard, and registers them as the consuming party information 212 with the database. Note that the utilization plan documents are not limited to being presented at the time of signing of the contracts, and may be presented, for example, at any timing on the consumers' side. Each time a utilization plan document is presented, the CPU 201 performs an update by registering the content of this utilization plan document as the consuming party information 212 with the database.

The processing of FIG. 7 is executed by the analysis unit 207, the optimization unit 209, and the evaluation unit 211 of the CPU 201. S401 to S403 are the same as the description of S301 to S303 of FIG. 6, and thus their description will be omitted.

In S404, the CPU 201 determines whether there is a difference between the operation statuses of respective resources of the energy management systems of the consuming parties 102 and the contents of the utilization plan documents presented from the consumers as a result of analysis in S403. Here, if it is determined that there is a difference, the processing proceeds to S405, and if it is determined that there is no difference, the processing proceeds to S406.

Basically, the EMS control unit 204 of the aggregator 101 operates respective resources of the energy management systems of the consuming parties 102 in conformity with the utilization plan documents presented from the consumers. However, for example, there may be a case where even if the EMS control unit 204 has activated the resources in conformity with the utilization plan documents, the consumers thereafter stop the operations of these resources. Furthermore, there may also be a case where even though the utilization plan documents presented from the consumers describe that the operations of onboard batteries of electric vehicles are permitted in a predetermined time section, the electric vehicles are in use for the purpose of travel when the EMS control unit 204 makes an attempt to charge. In addition, there may also be a case where the consumers frequently cancel or update the presentation of the utilization plans.

Therefore, when an instruction for activation or cessation of operation has been received from the EMS control unit 204 of the aggregator 101, if the state of a target resource is the state where this instruction cannot be carried out, the EMS control unit 226 of a consuming party 102 notifies the EMS control unit 204 of the aggregator 101 to that effect. Then, in S405, the CPU 201 notifies the consuming party 102 of the inability to operate in conformity with the presented utilization plan document via the network 106. For example, the CPU 201 may transmit a notification mail to a mobile terminal of the consumer via the network 106 based on the consuming party information 212.

In proceeding from S405 to S406, the CPU 201 sets a negative evaluation with respect to a consuming party 102 for whom there was a difference as a result of the determination of S404. On the other hand, in proceeding from S404 to S406, the CPU 201 sets a positive evaluation with respect to a consuming party 102 for whom there was no difference as a result of the determination of S404. Here, an evaluation serves as, for example, a base for deciding on the price of compensation to be paid to a consumer, and is an index of reliability (reliability degree) of the consumer. The reliability degree is lowered when a negative evaluation is set, and the reliability degree is increased when a positive evaluation is set. Then, at the stage of payment of compensation from the aggregator 101 to a consumer, the price of compensation is decided on based on a cumulative value of the reliability degree at that point.

In S407, with use of the result of analysis in S403, the CPU 201 optimizes the operations of respective resources of the energy management systems of the consuming parties 102 so as to satisfy the request from the electricity business operator 104 to control the electric power demand. The optimization at this time is performed based on the result of analysis in S403, even if it was determined that there was a difference in S404.

As described above, when the resources of the energy management system of a consuming party 102 are not operating in conformity with the utilization plan presented from a consumer, a negative evaluation is set with respect to this consumer. With this configuration, the consumer can be evaluated using the utilization plan presented from the consumer, and this can be reflected in the setting of the price of compensation.

An evaluation with respect to a. consumer may be decided on in accordance with, for example, the time of presentation of a utilization plan document from the consumer. For example, when there is a predetermined period or longer until the time of execution that is desired by a consumer with respect to the content of a presented utilization plan document, this is regarded as an early presentation, and a positive evaluation is set with respect to this consumer. On the other hand, when there is less than the predetermined period, a negative evaluation is set with respect to this consumer. Furthermore, an evaluation with respect to a consumer may be decided on in accordance with the frequency of change in a utilization plan document from the consumer. In this case, a positive evaluation is set when the frequency of change is lower than a predetermined number of times within a unit period, and a negative evaluation is set when the frequency of change is equal to or higher than the predetermined number of times.

The following describes a case where the extent of the request for demand control from the electricity business operator 104 is large. For example, when electricity generation equipment has been damaged by an earthquake and the like, the electric power supply capability of the electricity business operator 104 is expected to decrease significantly. In this case, in order to prevent a large-scale blackout and the like, the consuming parties 102 may be requested to make a maximum effort to save electricity. In such a situation, if the resources of the energy management systems of the consuming parties 102 are operated in line with the utilization plans presented from the consumers, there is a possibility that the amount of restraint in the demand requested from the electricity business operator 104 cannot be met. In this case, the aggregator 101 performs optimization so as to meet the amount of restraint in the demand requested from the electricity business operator 104, and then determines whether there is a difference from the utilization plans presented from the consumers. With respect to a consumer for whom there was a difference as a result of the determination, it is considered that cooperation to realize the amount of restraint in the demand has been provided, and a positive evaluation is made.

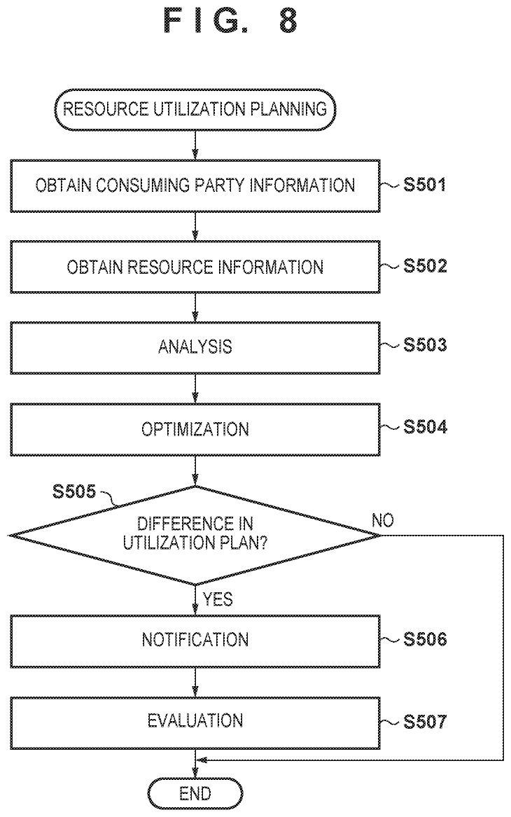

FIG. 8 is a flowchart showing processing of resource utilization planning in a situation where the consumers have presented the resource utilization plans and the extent of the request for demand control is large. The processing of FIG. 8 is executed by the analysis unit 207, the optimization unit 209, and the evaluation unit 211 of the CPU 201. S501 to S504 are the same as the description of S301 to S304 of FIG. 6, and thus their description will be omitted.

In S505, the CPU 201 determines whether there is a difference between the operation statuses of respective resources of the energy management systems of the consuming parties 102 and the contents of the utilization plan documents presented from the consumers as a result of analysis in S503. Here, if it is determined that there is a difference, the processing proceeds to S506, and if it is determined that there is no difference, the processing of FIG. 8 is ended.

Basically, the EMS control unit 204 of the aggregator 101 operates respective resources of the energy management systems of the consuming parties 102 in conformity with the utilization plan documents presented from the consumers. However, as stated earlier, if the resources are operated in conformity with the utilization plan documents, there is a possibility that the amount of restraint in the demand from the electricity business operator 104 cannot be met. Therefore, irrespective of the utilization plans presented from the consumers, the resource operations are optimized based on the result of analysis of the resource information 213, similarly to the processing of FIG. 6.

In S506, the CPU 201 notifies a consuming party 102 of the inability to operate in conformity with the presented utilization plan document via the network 106. For example, the CPU 201 may transmit a notification mail to a mobile terminal of the consumer via the network 106 based on the consuming party information 212.

In S507, the CPU 201 sets a positive evaluation with respect to a consuming party 102 for whom there was a difference as a result of the determination of S505. This evaluation, similarly to the evaluation in FIG. 7, serves as a base for deciding on the price of compensation to be paid to the consumer, and is an index of reliability (reliability degree) of the consumer. Regarding the evaluation, at the stage of payment of compensation from the aggregator 101 to a consumer, the price of compensation is decided on based on a cumulative value of the reliability degree at that point.

As described above, in a situation where the extent of the request for demand control is large, the resource operations of the energy management systems of the consuming parties 102 are optimized irrespective of the utilization plans presented from the consuming parties. Then, when there is a difference from a presented utilization plan, an evaluation with respect to the relevant consuming party is increased. This configuration can improve the consumers' motivations to cooperate in the restraint of the demand.

The sets of processing of FIG. 6 to FIG. 8 are not limited to being utilized in such a manner that one of the sets of processing is uniformly used in the VPP system, and processing to be used may vary with each consuming party 102. Alternatively, for example, provided that a consumer was at first participating in the VPP service through the method of FIG. 7 in which the utilization plan document is presented to the aggregator 101, when an evaluation point has become equal to or higher than a predetermined value, the consumer may be able to receive the VPP service through the method of FIG. 6 in which the consumer need not present the utilization plan.

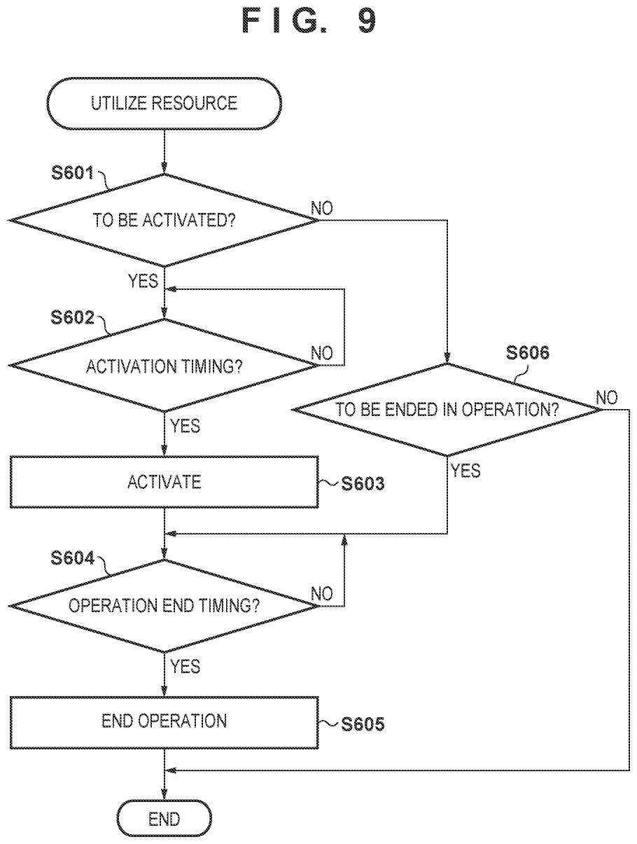

FIG. 9 is a flowchart showing processing for controlling the operations of the resources of the energy management systems of the consuming parties 102. The processing of FIG. 9 is executed in resource utilization in step 304 of FIGS. 3A and 3B. The processing of FIG. 9 is executed by the EMS control unit 204 under instruction from the CPU 201 of the aggregator 101.

In S601, the EMS control unit 204 determines whether a resource to be used as a target (target resource) among the resources of the energy management systems of the consuming parties 102 is to be activated. For example, the determination may be made depending on whether the activation is possible with the obtainment of life information from the resource information 213. If it is determined that the target resource is to be activated in S601, the processing proceeds to S602, and if it is determined that the target resource is not to be activated, the processing proceeds to S606.

In S606, the EMS control unit 204 determines whether the target resource is to be ended in operation. The determination of S606 may be made depending on, for example, whether the operation can be ended. For example, when a consumer has stopped the operation even though the target resource was activated in conformity with the utilization plan that was presented from the consumer or optimized by the optimization unit 209, it is determined that the operation cannot be ended, and the processing of FIG. 9 is ended. In this case, the EMS control unit 204 may notify the consumer to that effect. If it is determined that the target resource is to be ended in operation in S606, the processing proceeds to S604, and if it is determined that the target resource is not to be ended in operation, the processing of FIG. 9 is ended.

In S602, the EMS control unit 204 waits for an activation timing of the target resource based on the utilization plan that was presented from the consumer or optimized by the optimization unit 209. Upon arrival of the activation timing, the processing proceeds to S603, the EMS control unit 204 instructs the EMS control unit 226 to activate the target resource via the EMS network 103, and the EMS control unit 226 activates the target resource.

In S604, the EMS control unit 204 waits for an operation end timing of the target resource that is in operation. Upon arrival of the operation end timing, the processing proceeds to S605, the EMS control unit 204 instructs the EMS control unit 226 to end the operation of the target resource via the EMS network 103, and the EMS control unit 226 ends the operation of the target resource.

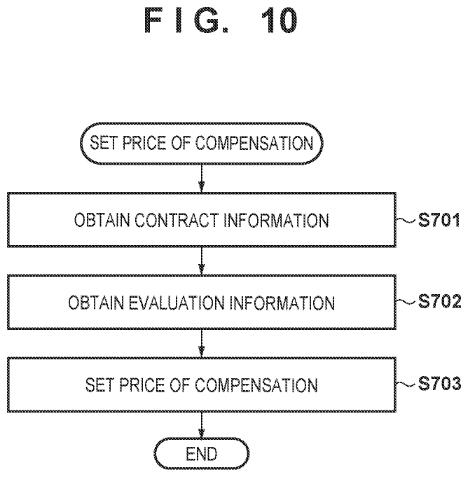

FIG. 10 is a flowchart showing processing for setting the prices of compensation. The processing of FIG. 10 is executed by the CPU 201, and is executed in, for example, step 307 of FIG. 3A.

In S701, the CPU 201 obtains contract information of the VPP service from the consuming party information 212. The obtained contract information is, for example, information related to compensation, such as the type of the VPP service, the time of payment, and the calculation method.

In S702, the CPU 201 obtains evaluation information related to the consumers of the consuming parties 102. The evaluation information obtained here is evaluation information that was set by the evaluation unit 211 of the CPU 201 in S406 of FIG. 7 and S507 of FIG. 8.

In S703, the CPU 201 sets the prices of compensation to be paid to the consumers based on the evaluation information obtained in S702. For example, the prices of compensation are calculated based on the calculation method obtained in S701. Thereafter, the processing of FIG. 10 is ended.

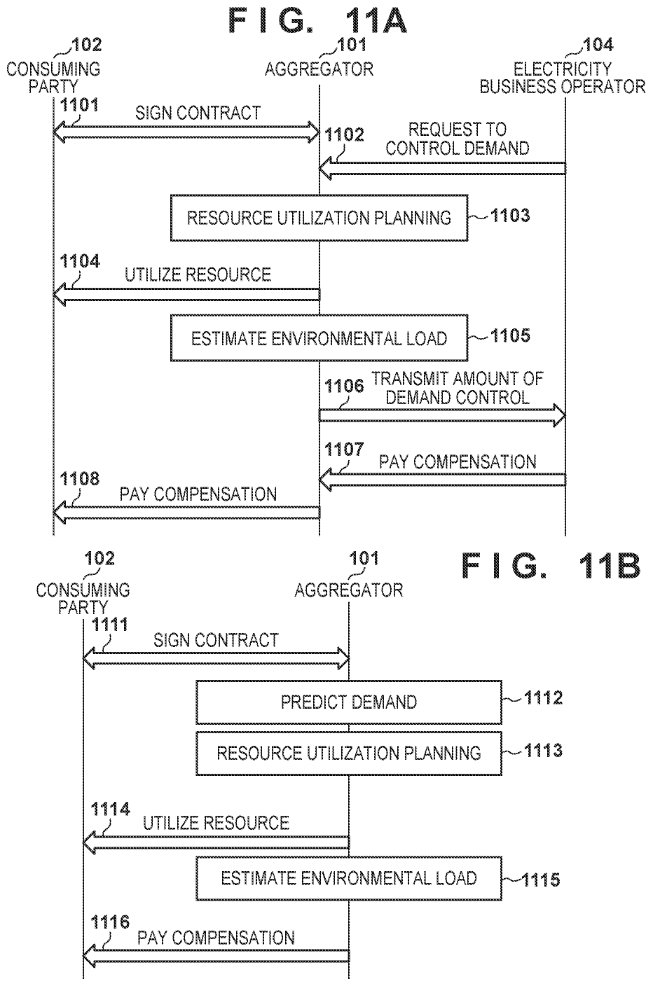

The following describes other sequences of processing that is performed among the aggregator 101, the consuming party 102, and the electricity business operator 104. FIG. 11A is a sequence diagram showing processing that is performed among the aggregator 101, the consuming party 102, and the electricity business operator 104 in the VPP system of FIG. 1. First, in step 1101, a contract for using the VPP service is signed between the consuming party 102 and the aggregator 101. Thereafter, the aggregator 101 receives a request from the electricity business operator 104 to control the electric power demand in step 1102, and then plans utilization of the resources of the energy management system of the consuming party 102 based on the result of analysis by the analysis unit 207 in step 1103. Here, the request from the electricity business operator 104 to control the electric power demand is, for example, a request to restrain or promote the electric power demand. Then, in step 1104, the aggregator 101 utilizes the resources of the energy management system of the consuming party 102 in conformity with the utilization plan. In step 1105, the aggregator 101 estimates environmental loads associated with the operations of respective resources of the energy management system of the consuming party 102. In step 1106, the aggregator 101 transmits a record of control on the electric power demand (the amount of demand control) to the electricity business operator 104. Thereafter, in step 1107, the electricity business operator 104 pays compensation corresponding to the record to the aggregator 101. Then, in step 1108, the aggregator 101 pays compensation (incentive) to the consuming party 102 based on the estimated environmental loads.

In FIG. 11A, the utilization of resources is started after receiving the request from the electricity business operator 104 to control the electric power demand; meanwhile, in FIG. 11B, the utilization of resources is started after the aggregator 101 has predicted the electric power demand. First, in step 1111, a contract for using the VPP service is signed between the consuming party 102 and the aggregator 101. Thereafter, in step 1112, based on the result of analysis by the analysis unit 207, the aggregator 101 predicts a fluctuation in the electric power demand throughout the region managed by the aggregator 101. Then, in step 1113, the aggregator 101 plans the utilization of the resources of the energy management system of the consuming party 102 based on the result of analysis by the analysis unit 207 so as to reduce the predicted fluctuation in the electric power demand. Then, in step 1114, the aggregator 101 utilizes the resources of the energy management system of the consuming party 102 in conformity with the utilization plan. In step 1115, the aggregator 101 estimates environmental loads associated with the operations of respective resources of the energy management system of the consuming party 102. Then, in step 1116, the aggregator 101 pays compensation to the consuming party 102 based on the estimated environmental loads.

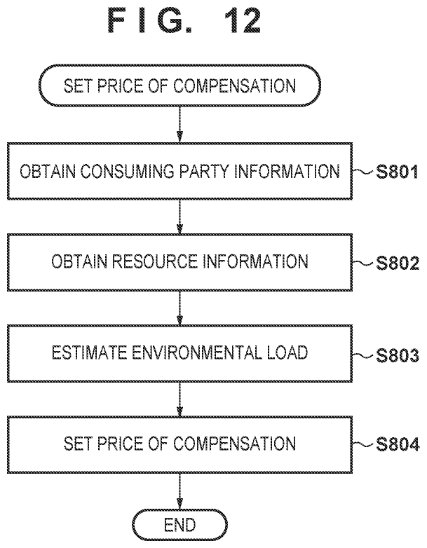

FIG. 12 is a flowchart showing processing for setting the price of compensation. The processing of FIG. 12 is executed by the CPU 201, and is executed in, for example, step 1105 of FIG. 11A and FIG. 11B.

In S801, the CPU 201 obtains contract information of the VPP service from the consuming party information 212. The obtained contract information is, for example, information related to compensation, such as the type of the VPP service, the time of payment, and the calculation method. In S802, the CPU 201 obtains the resource information 213 registered with the database in relation to the resources that have been utilized in step 1104.

In S803, based on the resource information 213 obtained in S802, the CPU 201 estimates the amounts of environmental loads attributed to the resource operations. The following describes the estimation of the amounts of environmental loads.

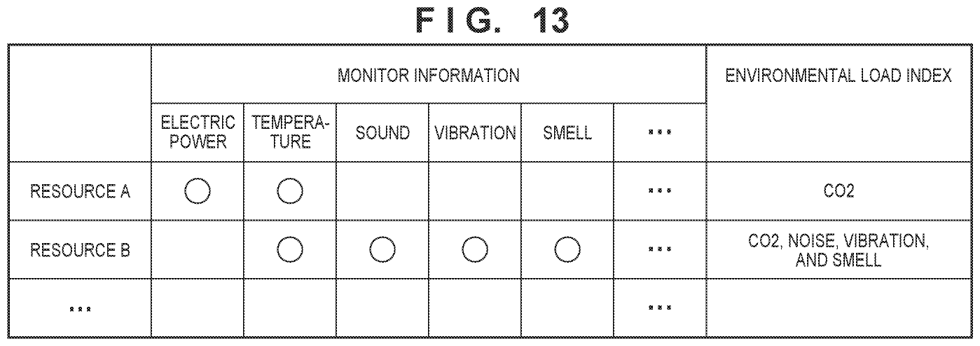

FIG. 13 is a table showing examples of environmental load indexes that are used by the CPU 201 in estimating the amounts of environmental loads. The table of FIG. 13 is stored, for example, as the environmental load indexes 214 in the storage unit 203.

The table shown in FIG. 13 is generated in correspondence with each consuming party 102. The sections of resources A, B, . . . correspond to, for example, electric power devices that are obtained from the consuming party information 212 and owned by the consumer. The sections of monitor information indicate, for example, information that should be obtained through monitoring when respective resources have been operated. Regarding the resource A, which is an air conditioner for example, monitoring of electric power information and temperature information is indicated. On the other hand, regarding the resource B, which is an engine-type electric generator for example, monitoring of temperature information, sound information, vibration information, and information related to a smell is indicated. For example, measured values from sensors that are respectively provided for the resources are monitored as the aforementioned various types of information.

The sections of environmental load indexes indicate environmental load indexes of the amounts of environmental loads to be estimated. For example, in the case of the resource A, the amount of CO₂ emission is estimated based on the electric power information and the temperature information. For example, the amount of CO₂ emission may be obtained from a calculation formula based on the amount of CO₂ emission per unit amount of electric power, which has been set in accordance with the type of the electric power device, and on a period of operation and the number of operated devices. On the other hand, in the case of the resource B, the amounts of environmental loads related to noise (noise pollution), vibration, and a smell are estimated in addition to the amount of CO₂ emission. The amounts of environmental loads are not limited to a method in which they are obtained directly from monitor information, and it is possible to use a method in which they are obtained indirectly. For example, a noise pollution level may be estimated as the amount of environmental load from a preset relationship between a driving output and noise pollution. The environmental load indexes are not limited to those described above, and other indexes may be used. For example, in the case of an industrial consuming party 102, nitrogen oxides (NOₓ) and sulfur oxides (SOₓ) may be used as environmental load indexes.

In S804, the CPU 201 sets the price of compensation to be paid to the consumer based on the amounts of environmental loads estimated in S803. For example, for each of the aforementioned environmental load indexes, a proportion of the amount of the environmental load to a threshold is obtained, and an average value of these proportions is calculated. For example, with respect to the resource B, provided that the proportions of the amount of CO₂ emission, noise, vibration, and a smell to their respective thresholds are 0.7, 1.1, 0.9, and 0.5, an average value=0.8 is calculated. Then, the amount of money obtained by dividing a reference-base price of compensation by the average value is set as the price of compensation. An average value smaller than 1.0 indicates that the amounts of environmental loads are kept small. In this case, the lower the environmental loads relative to the thresholds, the higher the price of compensation; this can improve the consumer's motivation to operate electric power devices with low environmental loads. On the other hand, the higher the environmental loads relative to the thresholds, the lower the price of compensation; this can cause the consumer to restrain from operating electric power devices with high environmental loads. Furthermore, a calculation method other than the aforementioned example may be used as long as the aforementioned advantageous effects can be achieved. After S804, the processing of FIG. 12 is ended.

The aforementioned thresholds may be allocated in such a manner that they vary with each predetermined time section or each day. For example, with regard to noise, strict conditions may be provided for noise determination by setting the threshold during night-time to be smaller than the threshold during daytime.

### Summary of Each Embodiment

A management apparatus according to the above-described embodiment is a management apparatus that manages an electric power device of an electric power consumer, comprising: an obtaining unit configured to obtain (S303) characteristic information of the electric power device as information related to an environmental load; and a planning unit configured to plan (S304) a priority rank of an operation of the electric power device in utilization of electric power of the electric power device based on the characteristic information obtained by the obtaining unit. With this configuration, the operation of the electric power device can be optimally planned for the consumer.

Furthermore, the management apparatus further comprises a surveillance unit configured to surveil (FIG. 4) the operation of the electric power device of the electric power consumer, wherein the obtaining unit obtains the characteristic information of the electric power device based on information obtained from a result of surveillance by the surveillance unit. With this configuration, the characteristic information of the electric power device can be obtained through surveillance of the operation of the electric power device.

Furthermore, the information obtained from the result of surveillance by the surveillance unit includes at least one of an amount of electric power use and sensor information. With this configuration, the amount of electric power use and the sensor information can be used in the planning of the priority rank of the operation of the electric power device.

The characteristic information includes a status of use by the electric power consumer. With this configuration, the priority rank of the operation of the electric power device can be planned based on the status of use of the electric power device by the electric power consumer.

Furthermore, the electric power device includes an onboard battery of an electric vehicle, and the obtaining unit obtains intended travel information of the electric vehicle as the status of use by the electric power consumer. With this configuration, the intended travel information of the electric vehicle can be used in the planning of the priority rank of the operation of the electric power device.

Furthermore, the characteristic information includes property information of the electric power device, and the planning unit plans the priority rank of the operation of the electric power device based on information indicating a state of the electric power consumer and on the property information of the electric power device. The property information of the electric power device includes at least one of an activation period, a stabilization period, and standby power. With this configuration, the priority rank of the operation of the electric power device can be planned based on the information indicating the state of the electric power consumer, and on the activation period, the stabilization period, the standby power, and the like of the electric power device.

The property information of the electric power device includes at least one of noise, an amount of vibration, and emission. With this configuration, the priority rank of the operation of the electric power device can be planned based on, for example, noise, an amount of vibration, and emission.

Furthermore, the management apparatus further comprises a second obtaining unit configured to obtain a utilization plan for the electric power device, wherein when the second obtaining unit has obtained the utilization plan, the planning unit plans the priority rank of the operation of the electric power device based on the obtained utilization plan instead of the characteristic information. With this configuration, when the utilization plan has been obtained from, for example, the electric power consumer, the priority rank of the operation of the electric power device can be planned based on the utilization plan.

Furthermore, the management apparatus further comprises: a determination unit configured to determine whether the electric power consumer is operating the electric power device in conformity with the utilization plan obtained by the second obtaining unit; and an evaluation unit configured to evaluate the electric power consumer in accordance with a result of determination by the determination unit. With this configuration, whether the electric power consumer is operating the electric power device in conformity with the utilization plan can be determined, and the electric power consumer can be evaluated based on the result of this determination.

Furthermore, the evaluation unit evaluates the electric power consumer further in accordance with the time at which the second obtaining unit obtains the utilization plan from the electric power consumer. With this configuration, the electric power consumer can be evaluated in accordance with the time at which the utilization plan is obtained from the electric power consumer.

Furthermore, the electric power device includes at least one of a storage battery, a fuel cell, and an electric generator. With this configuration, the priority ranks of the operations of the storage battery, the fuel cell, the electric generator, and the like can be planned.

Furthermore, the management apparatus, when the obtaining unit obtains information related to an operation status of the electric power device as the characteristic information of the electric power device (S802), further comprises: an estimation unit configured to estimate (S803) an amount of an environmental load attributed to the operation of the electric power device based on the information related to the operation status obtained by the obtaining unit; and a decision unit configured to decide (S804) on an incentive for the electric power consumer based on the amount of the environmental load estimated by the estimation unit. With this configuration, the amount of the environmental load can be reflected in the setting of the incentive.

Furthermore, the obtaining unit obtains information that has been measured by a measuring unit provided for the electric power device as the information related to the operation status. The information related to the operation status includes at least one of an amount of electric power, a temperature, sound, and an amount of vibration. With this configuration, for example, an amount of electric power, a temperature, sound, and an amount of vibration from a sensor provided for the electric power device can be obtained as the information related to the operation status.

Furthermore, the estimation unit estimates the amount of the environmental load for each of environmental load indexes based on the information related to the operation status. With this configuration, the amount of the environmental load can be estimated for each of the environmental load indexes.

Furthermore, the management apparatus further comprises a storage unit configured to store information in which the electric power device is associated with the information related to the operation status to be obtained by the obtaining unit. The information stored in the storage unit is that at least one of the environmental load indexes is associated per electric power device. This configuration makes it possible to configure, for example, a database in which the information related to the operation status to be obtained is prescribed per electric power device.

Furthermore, the environmental load indexes includes at least one of an amount of CO₂ emission, sound, vibration, and a smell. With this configuration, the amount of the environmental load can be obtained with respect to each of an amount of CO₂ emission, sound, vibration, and a smell.

Furthermore, the decision unit is that the smaller the amount of the environmental load estimated by the estimation unit, the larger the decided incentive. Moreover, the decision unit is that the larger the amount of the environmental load estimated by the estimation unit, the smaller the decided incentive. This configuration can improve the motivation of the electric power consumer to use an electric power device with a small environmental load.

The information related to the operation status is information related to an operation for restraining or promoting electric power of the electric power device. This configuration can improve the motivation to use an electric power device with a small environmental load as, for example, an electric power device for dealing with a demand response.

The present invention is not limited to the above-described embodiment, and various changes and modifications are possible without departing from the spirit and the scope of the present invention. Therefore, to apprise the public of the scope of the present invention, the following claims are made.

What is claimed is:

1. A management apparatus that manages an electric power device of an electric power consumer, comprising:
an obtaining unit configured to obtain characteristic information of the electric power device as information related to an environmental load; and
a planning unit configured to plan a priority rank of an operation of the electric power device in utilization of electric power of the electric power device based on the characteristic information obtained by the obtaining unit.

2. The management apparatus according to claim 1, further comprising:
a surveillance unit configured to surveil the operation of the electric power device of the electric power consumer,
wherein the obtaining unit obtains the characteristic information of the electric power device based on information obtained from a result of surveillance by the surveillance unit.

3. The management apparatus according to claim 2, wherein
the information obtained from the result of surveillance by the surveillance unit includes at least one of an amount of electric power use and sensor information.

4. The management apparatus according to claim 1, wherein
the characteristic information includes a status of use by the electric power consumer.

5. The management apparatus according to claim 4, wherein
the electric power device includes an onboard battery of an electric vehicle, and
the obtaining unit obtains intended travel information of the electric vehicle as the status of use by the electric power consumer.

6. The management apparatus according to claim 1, wherein
the characteristic information includes property information of the electric power device, and
the planning unit plans the priority rank of the operation of the electric power device based on information indicating a state of the electric power consumer and on the property information of the electric power device.

7. The management apparatus according to claim 6, wherein
the property information of the electric power device includes at least one of an activation period, a stabilization period, and standby power.

8. The management apparatus according to claim 1, wherein
the property information of the electric power device includes at least one of noise, an amount of vibration, and emission.

9. The management apparatus according to claim 1, further comprising:
a second obtaining unit configured to obtain a. utilization plan for the electric power device,
wherein when the second obtaining unit has obtained the utilization plan, the planning unit plans the priority rank of the operation of the electric power device based on the obtained utilization plan instead of the characteristic information.

10. The management apparatus according to claim 9, further comprising:
a determination unit configured to determine whether the electric power consumer is operating the electric power device in conformity with the utilization plan obtained by the second obtaining unit; and
an evaluation unit configured to evaluate the electric power consumer in accordance with a result of determination by the determination unit.

11. The management apparatus according to claim 10, wherein
the evaluation unit evaluates the electric power consumer further in accordance with the time at which the second obtaining unit obtains the utilization plan from the electric power consumer.

12. The management apparatus according to claim 1, wherein
the electric power device includes at least one of a storage battery, a fuel cell, and an electric generator.

13. The management apparatus according to claim 1, wherein, when the obtaining unit obtains information related to an operation status of the electric power device as the information related to the environmental load, further comprising:
an estimation unit configured to estimate an amount of an environmental load attributed to the operation of the electric power device based on the information related to the operation status obtained by the obtaining unit; and
a decision unit configured to decide on an incentive for the electric power consumer based on the amount of the environmental load estimated by the estimation unit.

14. The management apparatus according to claim 13, wherein
the obtaining unit obtains information that has been measured by a measuring unit provided for the electric power device as the information related to the operation status.

15. The management apparatus according to claim 13, wherein
the information related to the operation status includes at least one of an amount of electric power, a temperature, sound, and an amount of vibration.

16. The management apparatus according to claim 13, wherein
the estimation unit estimates the amount of the environmental load for each of environmental load indexes based on the information related to the operation status.

17. The management apparatus according to claim 13, wherein
the smaller the amount of the environmental load estimated by the estimation unit, the larger the incentive that is decided on by the decision unit.

18. The management apparatus according to claim 13, wherein
the information related to the operation status is information related to an operation for restraining or promoting electric power of the electric power device.

19. An apparatus that is capable of communicating with the management apparatus according to claim 1 via a network and that is provided for a system of the electric power consumer including the electric power device, comprising:
a surveillance unit configured to surveil an operation of the electric power device of the electric power consumer; and
a transmission unit configured to transmit, to the management apparatus via the network, the information related to the environmental load that has been obtained based on information obtained from a result of surveillance of the surveillance unit.

20. A computer-readable storage medium that stores a program that, in order to manage an electric power device of an electric power consumer, causes a computer to execute:
an obtaining step of obtaining characteristic information of the electric power device as information related to an environmental load; and
a planning step of planning a priority rank of an operation of the electric power device in utilization of electric power of the electric power device based on the characteristic information obtained in the obtaining step.
